(19) United States
(12) Patent Application Publication
(10) Pub. No.: US 2026/0301624 A1
(43) Pub. Date: Oct. 1, 2026

(54) DRIVER CIRCUIT

(71) Applicant: Novatek Microelectronics Corp., Hsinchu (TW)

(72) Inventor: Chi-Ting Chen, Hsinchu City (TW)

(73) Assignee: Novatek Microelectronics Corp., Hsinchu (TW)

(21) Appl. No.: 19/096,707

(22) Filed: Mar. 31, 2025

(51) Int. Cl. G09G 3/20; H03K 17/687

(52) U.S. Cl. CPC G09G 3/20; H03K 17/6871; G09G 2310/027; G09G 2310/0291; G09G 2330/028

(57) ABSTRACT

A driver circuit including a buffer circuit and at least one charge and discharge circuit is provided. The buffer circuit is coupled to a first resistor string and a digital-to-analog converter via a trace. The buffer circuit is configured to output an input voltage to the first resistor string via the trace. The trace is coupled between the buffer circuit and the digital-to-analog converter. The charge and discharge circuit is coupled to the buffer circuit via the trace. The charge and discharge circuit is configured to charge or discharge the trace according to a first control signal.

### BACKGROUND

### Technical Field

The invention relates to a driver circuit, more specifically, to a driver circuit configured to drive a display panel.

### Description of Related Art

The output voltages of display panel source drivers are defined by resistor strings. Gamma operational amplifier (GOP) are used to provide driving capability for the resistor strings, thereby increasing the slew rates of digital-to-analog converters (DACs). However, if the RC (resistance and capacitance) ladder of the DAC input is closer to the GOP connection node, the slew rate will be faster and the source driver can have a faster transient response. On the other hand, if the voltage selected by the DAC input is further away from the RC ladder of the GOP connection node, the RC time constant formed by this path will cause the DAC output to recover too slowly, which will affect the source driver and then cause the display abnormality.

### SUMMARY

The invention is directed to a driver circuit, capable of charging or discharging a trace connected to the DAC input, to improve the slew rate of the voltage signal on the trace.

An invention of an embodiment provides a driver circuit, including a buffer circuit and at least one charge and discharge circuit. The buffer circuit is coupled to a first resistor string and a digital-to-analog converter via a trace. The buffer circuit is configured to output an input voltage to the first resistor string via the trace. The trace is coupled between the buffer circuit and the digital-to-analog converter. The charge and discharge circuit is coupled to the buffer circuit via the trace. The charge and discharge circuit is configured to charge or discharge the trace according to a first control signal.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a circuit diagram illustrating a display apparatus according to an embodiment of the invention.

FIG. 2 is a schematic diagram illustrating the driver circuit of FIG. 1 equipped with charge and discharge circuits according to an embodiment of the invention.

FIG. 3 is a circuit diagram illustrating a charge and discharge circuit according to an embodiment of the invention.

FIG. 4 is a circuit diagram illustrating a charge and discharge circuit according to another embodiment of the invention.

FIG. 5 is a circuit diagram illustrating a charge and discharge circuit according to another embodiment of the invention.

FIG. 6 is a circuit diagram illustrating a charge and discharge circuit according to another embodiment of the invention.

FIG. 7 is a circuit diagram illustrating a charge and discharge circuit according to another embodiment of the invention.

### DESCRIPTION OF THE EMBODIMENTS

The term "coupling (or connection)" used in the entire specification (including the claims) of the disclosure may refer to any direct or indirect connection means. For example, if a first device is described as being coupled (or connected) to a second device, it should be interpreted that the first device may be directly connected to the second device or the first device may be indirectly connected to the second device through another device or certain connection means. Terms such as "first" and "second" mentioned in the entire specification (including the claims) of the disclosure are used to name the elements or to distinguish between different embodiments or ranges, but not to limit the upper limit or the lower limit of the number of elements or to limit the sequence of the elements.

In addition, wherever possible, elements/components/steps using the same reference numerals in the drawings and the implementation manners represent the same or similar parts. Related descriptions of the elements/components/steps using the same reference numerals or using the same terminologies in different embodiments may be cross-referenced.

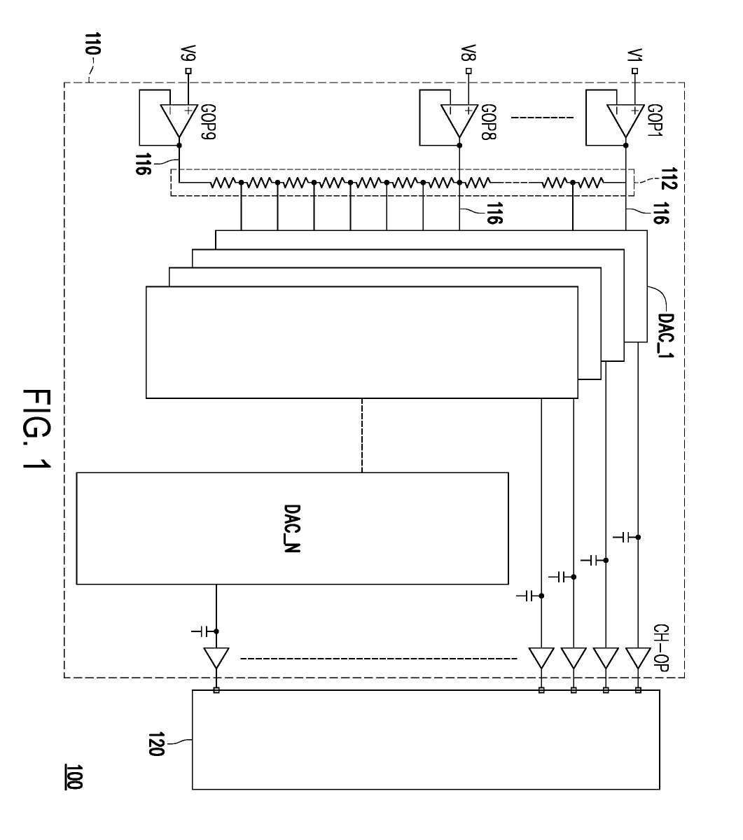

FIG. 1 is a circuit diagram illustrating a display apparatus according to an embodiment of the invention. Referring to FIG. 1, the display apparatus 100 includes a driver circuit 110 and a display panel 120. The driver circuit 110 is coupled to the display panel 120. The driver circuit 110 is configured to output driving signals to drive the display panel 120 to display images. In an embodiment, the driver circuit 110 is a display driver integrated circuit (DDIC), but the invention is not limited thereto.

The external input voltages V1 to V9 are provided to set the digital-to-analog converters (DACs) DAC_1 to DAC_N. To be specific, the buffer circuits GOP1 to GOP9 are coupled to the resistor string 112 and the DACs DAC_1 to DAC_N via traces 116, and configured to output the input voltages V1 to V9 to the resistor string 112 via traces 116, wherein the traces 116 are coupled between the buffer circuits GOP1 to GOP9 and the DACs DAC_1 to DAC_N. The buffer circuits GOP1 to GOP9 are configured to output the input voltages V1 to V9 to the resistor string 112 via traces 116. The buffer circuits GOP1 to GOP9 can enhance the driving capability of the input voltages V1 to V9. In an embodiment, the buffer circuit may include a unity-gain amplifier.

The resistor string 112 generates the gamma voltages, which serve as the correction voltages for the display brightness of the human eye, according to the input voltages V1 to V9. The gamma voltages generated by the resistor string 112 are then enhanced and outputted to the DAC of each channel for driving the display panel 120. The enhanced gamma voltages can accelerate the recovery speed of the DACs DAC_1 to DAC_N. The input voltage of channel operational amplifier CH-OP is provided by the corresponding DAC to drive the display panel 120. Therefore, the output voltages of the driver circuit 110 are determined by the resistor string 112.

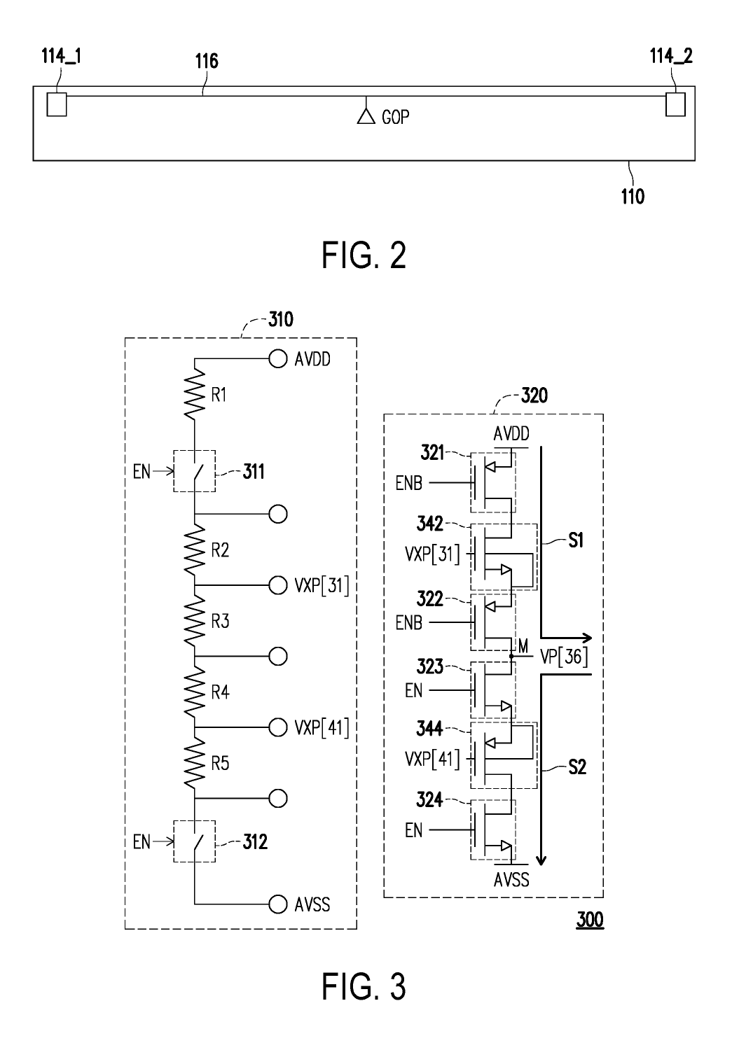

FIG. 2 is a schematic diagram illustrating the driver circuit of FIG. 1 equipped with charge and discharge circuits 114_1 and 114_2 according to an embodiment of the invention. Referring to FIG. 1 and FIG. 2, since the driver circuit 110 drives the display panel 120 from the center of the display panel 120 to both sides to maintain the symmetry of the trace 116, the buffer circuit GOP is placed in the center of the driver circuit 110. The trace 116 may be a connecting line between the DACs DAC_1 to DAC_N and the buffer circuits GOP1 to GOP9. However, the wider the driver circuit 110, the longer the distance of the trace. In high resolution applications, the charging or discharging time of the trance 116 is easily limited. In the present embodiment, in order to enhance the charging or discharging capability of trance 116, at least one charge and discharge circuit is configured to charge or discharge the trace 116. For example, the charge and discharge circuits 114_1 and 114_2 are coupled to the buffer circuit GOP via the trace 116 and disposed at two sides of the driver circuit 110.

FIG. 3 is a circuit diagram illustrating a charge and discharge circuit according to an embodiment of the invention. Referring to FIG. 3, the charge and discharge circuit 300 outputs a voltage signal VP via an output node M, and the voltage signal VP is applied to the trance 116 to charge or discharge the trance 116. The charge and discharge circuit 300 includes a resistor string 310 and a switch circuit 320.

To be specific, the resistor string 310 is configured to output voltage signals VXP (charge voltage) and VXP (discharge voltage) to the switch circuit 320. The resistor string 310 includes resistors R1 to R5 and switches 311 and 312. The resistors R1 to R5 and the switches 311 and 312 are coupled between a first operation voltage AVDD and a second operation voltage AVSS in series. The first operation voltage AVDD is larger than the second operation voltage AVSS. The switches 311 and 312 are controlled by a first control signal EN. When the switches 311 and 312 are conducted, the resistor string 310 generates and outputs the voltage signals VXP[31]. and VXP[41]. to the switch circuit 320. The voltage signal VXP[31]. is larger than the voltage signal VXP[41].

The switch circuit 320 is coupled to the resistor string 310. The switch circuit 320 receives the voltage signals VXP[41] and VXP[41]. from the resistor string 310. The switch circuit 320 is configured to output the voltage signal VP to the trance 116. The switch circuit 320 includes switches 321 to 324 and transistors 342 (first transistor) and 344 (second transistor). The switches 321 to 324 and the transistors 342 and 344 are coupled in series between the first operation voltage AVDD and the second operation voltage AVSS. The switches 321 and 322 are controlled by a second control signal ENB. The switches 323 and 324 are controlled by the first control signal EN. The second control signal ENB is an inverse signal of the first control signal EN. The transistor 342 receives the voltage signal VXP[31], and the transistor 344 receives the voltage signal VXP[41].

When the voltage signal VP[36] is increased and the slew rate of the voltage signal VP[36] is slow, a charging path S1 is conducted, and the voltage signal VP[36] is charged to VXP[31]-Vth, wherein Vth is a threshold voltage of the transistor 342. When the voltage signal VP[36] is decreased and the slew rate of the voltage signal VP[36] is slow, a discharging path S2 is conducted, and the voltage signal VP[36] is discharged to VXP[41]+Vth, wherein Vth is a threshold voltage of the transistor 344.

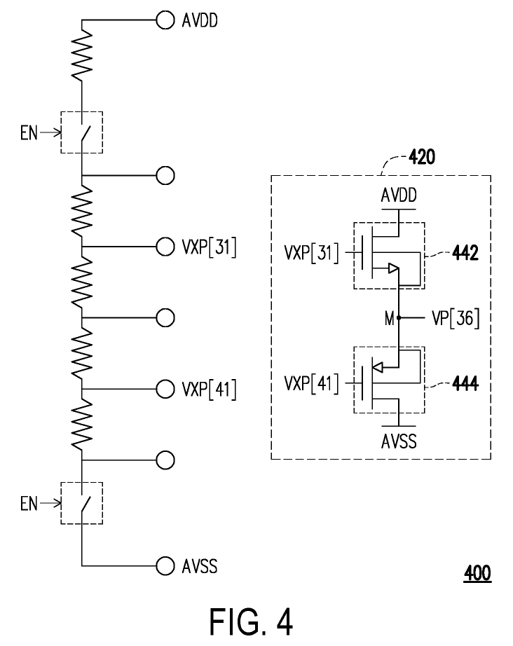

FIG. 4 is a circuit diagram illustrating a charge and discharge circuit according to another embodiment of the invention. Referring to FIG. 4, the charge and discharge circuit 400 is similar to the charge and discharge circuit 300, but the circuit structures of the switch circuits 320 and 420 are different. In the present embodiment, the switch circuit 420 simply includes two transistors 442 and 444 for charging or discharging the voltage signal VP.[36].

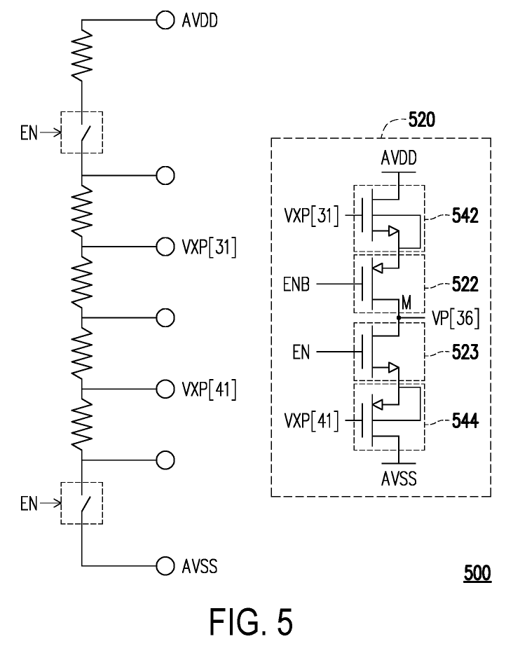

FIG. 5 is a circuit diagram illustrating a charge and discharge circuit according to another embodiment of the invention. Referring to FIG. 5, the charge and discharge circuit 500 is similar to the charge and discharge circuit 400, but the circuit structures of the switch circuits 420 and 520 are different. In the present embodiment, the switch circuit 520 further includes two switches 522 (first switch) and 523 (second switch) for controlling path conduction.

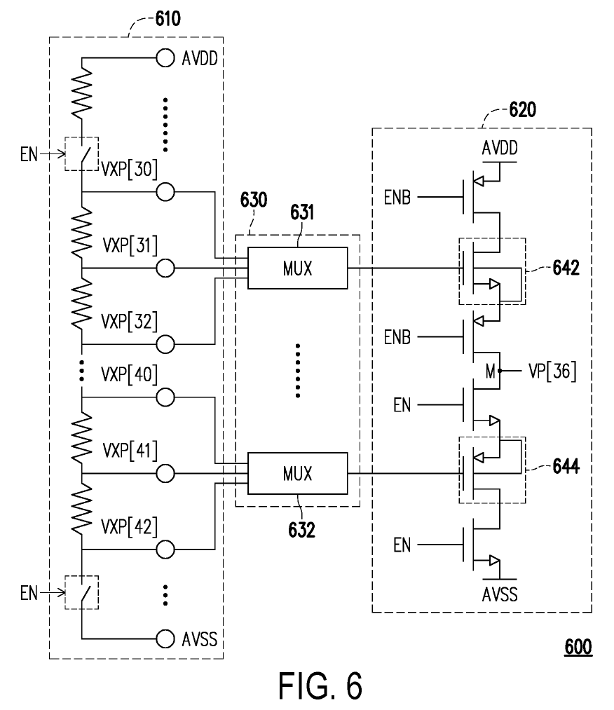

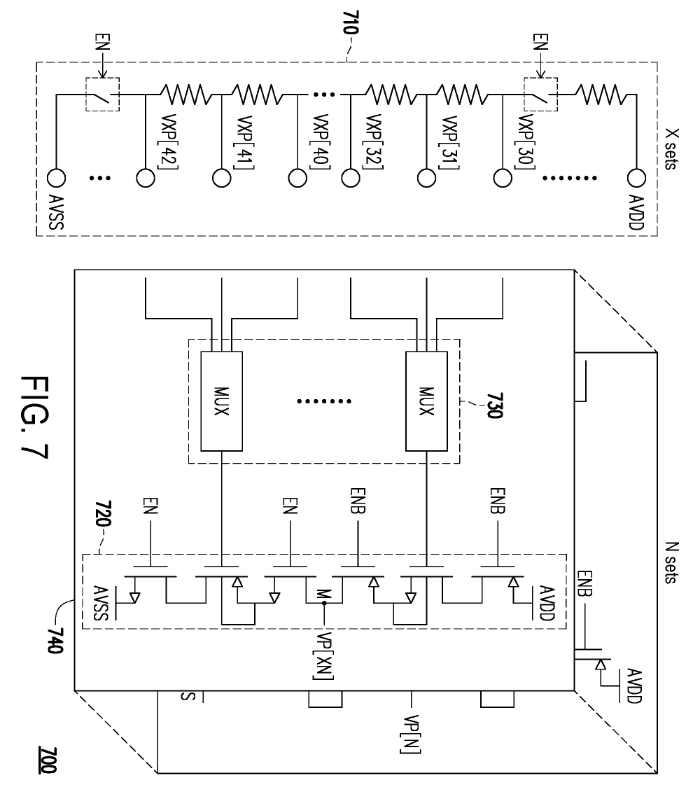

FIG. 6 is a circuit diagram illustrating a charge and discharge circuit according to another embodiment of the invention. Referring to FIG. 6, the charge and discharge circuit 600 is similar to the charge and discharge circuit 300, but the charge and discharge circuit 600 further includes a multiplexer circuit 630. The multiplexer circuit 630 is coupled between the resistor string 610 and the switch circuit 620.

The resistor string 610 is configured to output a plurality of voltage signals VXP[30] to VXP[32] (charge voltages) and VXP[40] to VXP[42] (discharge voltages) to the multiplexer circuit 630. The multiplexer circuit 630 includes a plurality of multiplexer MUX configured to select and output two voltage signals to the switch circuit 620. For example, the multiplexer 631 receives the voltage signals VXP[30], VXP[31], VXP[32] from the resistor string 610, and selects one voltage signal among the voltage signals VXP[30], VXP[31], VXP[32] and outputs the selected voltage signal to the transistor 642. Similarly, the multiplexer 632 receives the voltage signals VXP[40], VXP[41], VXP[42] from the resistor string 610, and selects one voltage signal among the voltage signals VXP[40], VXP[41], VXP[42] and outputs the selected voltage signal to the transistor 644. The switch circuit 620 may charge or discharge the voltage signal VP[36] with the selected voltage signal.

FIG. 7 is a circuit diagram illustrating a charge and discharge circuit according to another embodiment of the invention. Referring to FIG. 7, the charge and discharge circuit 700 includes X sets of resistor strings 710 and N sets of circuit blocks 740, wherein X and N are positive integers, and X is equal to N or not. Each of the circuit blocks 740 includes one switch circuit 720 and one multiplexer circuit 730. The charge and discharge circuit 700 is configured to output the voltage signals VP[N] to VP[XN] to respective traces.

In summary, in the embodiments of the invention, the driver circuit includes at least one charge and discharge circuit. The charge and discharge circuit includes the resistor string for generating the charge voltage and the discharge voltage. The charge voltage and the discharge voltage are configured to increase the slew rate of the voltage signal that is applied to the trace connected to the DAC input. Therefore, the driver circuit can charge or discharge the trace connected to the DAC input, to improve the slew rate of the voltage signal on the trace.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A driver circuit, comprising:
a buffer circuit, coupled to a first resistor string and a digital-to-analog converter via a trace, and configured to output an input voltage to the first resistor string via the trace, wherein the trace is coupled between the buffer circuit and the digital-to-analog converter; and
at least one charge and discharge circuit, coupled to the buffer circuit via the trace, and configured to charge or discharge the trace according to a first control signal.

2. The driver circuit according to claim 1, wherein the at least one charge and discharge circuit is configured to charge or discharge the trace according to a second control signal, wherein the second control signal is an inverse signal of the first control signal.

3. The driver circuit according to claim 1, wherein the at least one charge and discharge circuit comprises:
a second resistor string, coupled between a first operation voltage and a second operation voltage, and configured to output a charge voltage or a discharge voltage according to the first controlled signal; and
a switch circuit, coupled to the second resistor string, and configured to receive the charge voltage or the discharge voltage, and output a voltage signal to the trance,
wherein the voltage signal is charged by the charge voltage, or discharged by the discharge voltage.

4. The driver circuit according to claim 3, wherein the switch circuit is configured to output the voltage signal to the trance according to the first control signal and a second control signal, wherein the second control signal is an inverse signal of the first control signal.

5. The driver circuit according to claim 3, wherein the second resistor string comprises:
a plurality of resistors and at least one switch, coupled between the first operation voltage and the second operation voltage in series.

6. The driver circuit according to claim 5, wherein the plurality of resistors are configured to generate the charge voltage and the discharge voltage according to the first operation voltage and the second operation voltage.

7. The driver circuit according to claim 6, wherein the plurality of resistors output the charge voltage and the discharge voltage to the switch circuit when the at least one switch is conducted.

8. The driver circuit according to claim 5, wherein the first control signal is configured to control a conduction state of the at least one switch.

9. The driver circuit according to claim 3, wherein the switch circuit comprises:
a first transistor, coupled between the first operation voltage and an output node, and configured to receive the charge voltage, wherein the voltage signal is outputted from the output node; and
a second transistor, coupled between the output node and the second operation voltage, and configured to receive the discharge voltage.

10. The driver circuit according to claim 9, wherein the switch circuit further comprises:
at least one first switch, controlled by a second control signal, wherein the at least one first switch and the first transistor are coupled between the first operation voltage and the output node in series; and
at least one second switch, controlled by the first control signal, wherein the at least one second switch and the second transistor are coupled between the output node and the second operation voltage in series,
wherein the second control signal is an inverse signal of the first control signal.

11. The driver circuit according to claim 10, wherein when the at least one first switch is conducted, the voltage signal is charged by the charge voltage.

12. The driver circuit according to claim 10, wherein when the at least one second switch is conducted, the voltage signal is discharged by the discharge voltage.

13. The driver circuit according to claim 3, wherein the at least one charge and discharge circuit further comprises:
a multiplexer circuit, coupled between the second resistor string and the switch circuit, and configured to receive the charge voltage or the discharge voltage from the second resistor string, and select and output the charge voltage or the discharge voltage to the switch circuit.
